(19) United States
(12) Patent Application Publication
(10) Pub. No.: US 2011/0074991 A1
(43) Pub. Date: Mar. 31, 2011

(54) SOLID-STATE IMAGE DEVICE AND METHOD OF MANUFACTURING THE SAME

(75) Inventor: Hiroshi Sakoh, Kyoto (JP)

(73) Assignee: PANASONIC CORPORATION, Osaka (JP)

(21) Appl. No.: 12/957,787

(22) Filed: Dec. 1, 2010

Related U.S. Application Data
(63) Continuation of application No. PCT/JP2009/003515, filed on Jul. 27, 2009.

(30) Foreign Application Priority Data
Jul. 31, 2008 (JP) 2008-197124

(51) Int. Cl. H04N 5/335; H01L 31/18

(52) U.S. Cl. 348/279; 348/280; 438/70; 348/E05.091; 257/E31.127

(57) ABSTRACT

Light shielding films for preventing color mixture are disposed between Green filters 106 such that the light shielding films are located on the opposite corners of the Green filters 106 arranged in a checkered pattern, thereby preventing color mixture caused by light 111 diagonally incident from an invalid region between the Green filters 106 adjacent to each other in a diagonal direction of the Green filter 106. Since light shielding films for preventing color mixture are further disposed on the vertical and horizontal boundaries between adjacent pixels, it is possible to prevent the incident light 111 reflected on the light shielding film formed on a transfer electrode 102 from being incident on a light receiving portion 101 in the vertical and horizontal directions, thereby preventing color mixture from the adjacent pixels. Thus it is possible to suppress color mixture while keeping sensitivity characteristics, and prevent deterioration of image characteristics.

### FIELD OF THE INVENTION

The present invention relates to a solid-state image device in which a plurality of light receiving elements formed on a semiconductor substrate each have a color filter and a microlens, and a method of manufacturing the same.

### BACKGROUND OF THE INVENTION

In recent years, the number of pixels in a solid-state image device has increased and digital still cameras and mobile phone cameras have decreased in size.

Referring to FIGS. 13(a) and 13(b) and 14(a) and 14(b), a solid-state image device of the related art will be described below.

FIGS. 13(a) and 13(b) show the color filter configuration of the solid-state image device of the related art. FIG. 13(a) shows the configuration of color filters and FIG. 13(b) shows the pattern of a mask used for forming the color filters. FIGS. 14(a) and 14(b) are explanatory sectional views showing color mixture from an adjacent pixel in the solid-state image device of the related art. FIG. 14(a) shows adjacent pixels of different colors and FIG. 14(b) shows Green pixels.

FIG. 13(a) is a top view showing the color filters of the solid-state image device. In the solid-state image device of the related art, Green filters 106 are arranged in a checkered pattern and Blue filters 105 and Red filters 107 are alternately arranged between the Green filters 106. As shown in FIG. 13(b), in the mask pattern for forming the Green filters 106 in a checkered pattern, gaps are formed at opposite corners on the mask and the corners of rectangular patterns are cut off to increase a focus margin (e.g., see Japanese Patent Publication No. 8-8344).

### SUMMARY OF THE INVENTION

### Problem to be Solved by the Invention

In the related art, however, cells have decreased in size as digital still cameras and mobile phone cameras have recently decreased in size with higher pixel density. Further, skew ray components from adjacent pixels have increased as the exit pupils of camera lenses have decreased. Thus it has become necessary to address color mixture from adjacent pixels. FIGS. 14(a) and 14(b) are sectional views showing the valid pixels of the solid-state image device. FIG. 14(a) is taken along line A-A′ of FIG. 13(a) and FIG. 14(b) is taken along line B-B′ of FIG. 13(a). As shown in FIG. 14(b), since the gaps are formed at the opposite corners of the Green filters 106, incident light 111 of white light condensed through a microlens 110 is diagonally incident on a light receiving portion 101 from the adjacent Green filter 106 and causes color mixture. Further, as shown in FIG. 14(a), color mixture from adjacent pixels occurs also in vertical and horizontal directions such that the incident light 111 of the white light condensed through the microlens 110 is diagonally incident on the Green filter 106 from an adjacent Blue filter 105 and reaches the light receiving portion 101 of the Green filter 106. Such color mixture results in deterioration of characteristics, e.g., line crawl.

In view of the problem, an object of the present invention is to prevent deterioration of image characteristics by suppressing color mixture while keeping sensitivity characteristics.

### Means for Solving the Problem

In order to attain the object, a solid-state image device of the present invention includes: a plurality of light receiving portions formed on a substrate; Green filters formed in a checkered pattern on the light receiving portions; Blue filters and Red filters formed in alternate lines such that the Blue filters and the Red filters are placed between the Green filters in the alternate lines; a microlens formed on each of the Green filters, the Blue filters, and the Red filters; and first light shielding films for preventing color mixture, the first light shielding film being formed in a gap between the Green filters adjacent to each other in a diagonal direction.

Preferably, the solid-state image device further includes second light shielding films for preventing color mixture, wherein the second light shielding films are formed on the boundaries between the Blue filters and the Green filters and the boundaries between the Red filters and the Green filters, and the second light shielding film is smaller in thickness than the first light shielding film for preventing color mixture.

The first light shielding film for preventing color mixture may be a Black filter.

The first light shielding film for preventing color mixture and the second light shielding film for preventing color mixture may be Black filters.

The first light shielding film for preventing color mixture may be a film made up of the Blue filter and the Red filter.

The first light shielding film for preventing color mixture and the second light shielding film for preventing color mixture may be films each of which is made up of the Blue filter and the Red filter.

The Blue filter and the Red filter may be stacked.

A method of manufacturing a solid-state image device of the present invention, the solid-state image device including: a plurality of light receiving portions constituting a light receiving surface; color filters; and microlenses, the color filters and microlenses corresponding to the respective light receiving portions, when the color filters are formed, the method including the steps of: forming Green filters in a checkered pattern; forming first Black filters in gaps between the Green filters adjacent to each other in a diagonal direction; and forming Blue filters and Red filters.

Preferably, the method further includes the step of forming second Black filters on the boundaries between the Blue filters and the Green filters and the boundaries between the Red filters and the Green filters, concurrently with the step of forming the first Black filters, the second Black filter being smaller in thickness than the first Black filter.

The first Black filter may be replaced with a laminate of the Blue filter and the Red filter.

The first Black filter and the second Black filter may be each replaced with a laminate of the Blue filter and the Red filter.

A method of manufacturing a solid-state image device of the present invention, the solid-state image device including: a plurality of light receiving portions constituting a light receiving surface; color filters; and microlenses, the color filters and microlenses corresponding to the respective light receiving portions, when the color filters are formed, the method including the steps of: forming second Red filters acting as first light shielding films for preventing color mixture such that the second Red filters are formed in gaps between Green filters adjacent to each other in a diagonal direction, concurrently with first Red filters acting as the color filters; forming second Blue filters acting as the first light shielding films for preventing color mixture such that the second Blue filters are formed in the gaps between the Green filters adjacent to each other in the diagonal direction, concurrently with first Blue filters acting as the color filters; and forming the Green filters in a checkered pattern such that the first light shielding films for preventing color mixture are disposed in the gaps between the Green filters adjacent to each other in the diagonal direction, wherein the first light shielding film for preventing color mixture is configured such that the second Blue filter and the second Red filter are arranged in parallel.

Preferably, the method further includes the steps of: forming third Red filters on the boundaries between the first Blue filters and the Green filters in the step of forming the first and second Red filters, the third Red filter acting as a second light shielding film for preventing color mixture; and forming third Blue filters on the boundaries between the first Red filters and the Green filters in the step of forming the first and second Blue filters, the third Blue filter acting as the second light shielding film for preventing color mixture, wherein the second light shielding film for preventing color mixture is smaller in thickness than the first light shielding film for preventing color mixture.

### ADVANTAGE OF THE INVENTION

As previously mentioned, light shielding films for preventing color mixture are disposed between Green filters such that the light shielding films are located on the opposite corners of the Green filters arranged in a checkered pattern, thereby preventing color mixture caused by light diagonally incident from an invalid region between the Green filters adjacent to each other in a diagonal direction of the Green filter. Since the light shielding films for preventing color mixture are further disposed on the vertical and horizontal boundaries between adjacent pixels, it is possible to prevent the incident light reflected on the light shielding film formed on a transfer electrode from being incident on a light receiving portion in the vertical and horizontal directions, thereby preventing color mixture from the adjacent pixels. Thus it is possible to suppress color mixture while keeping sensitivity characteristics, thereby preventing deterioration of image characteristics.

### BRIEF DESCRIPTION OF THE DRAWINGS

FIG. 1 is a plan view showing the principle part of the configuration of a solid-state image device according to the present invention;

FIGS. 2(a) and 2(b) are sectional views showing the configuration of the solid-state image device according to a first embodiment;

FIGS. 3(a) and 3(b) are sectional views showing the configuration of a solid-state image device according to a second embodiment;

FIGS. 4(a) and 4(b) are sectional views showing the configuration of a solid-state image device in which light shielding films are formed by stacking Red filters on Blue filters according to a third embodiment;

FIGS. 5(a) and 5(b) are sectional views showing the configuration of the solid-state image device in which the light shielding films are formed by stacking the Blue filters on the Red filters according to the third embodiment;

FIGS. 6(a) and 6(b) are sectional views showing the configuration of a solid-state image device according to a fourth embodiment;

FIGS. 7(a) to 7(j) are process sectional views showing manufacturing process 1 of the solid-state image device according to the first embodiment;

FIGS. 8(a) to 8(j) are process sectional views showing manufacturing process 2 of the solid-state image device according to the first embodiment;

FIGS. 9(a) to 9(j) are process sectional views showing the manufacturing process of the solid-state image device according to the second embodiment;

FIGS. 10(a) to 10(f) are process sectional views showing the manufacturing process of the solid-state image device according to the third embodiment;

FIGS. 11(a) to 11(f) are process sectional views showing the manufacturing process of the solid-state image device according to the third embodiment;

FIGS. 12(a) to 12(j) are process sectional views showing the manufacturing process of the solid-state image device according to the fourth embodiment;

FIGS. 13(a) and 13(b) show the color filter configuration of a solid-state image device of the related art; and

FIGS. 14(a) and 14(b) are explanatory sectional views showing color mixture from an adjacent pixel in the solid-state image device of the related art.

### DESCRIPTION OF THE EMBODIMENTS

A solid-state image device to be installed in a camera according to the present invention is applicable to a CCD image sensor, a MOS image sensor, and so on. The following will describe a CCD image sensor as an example.

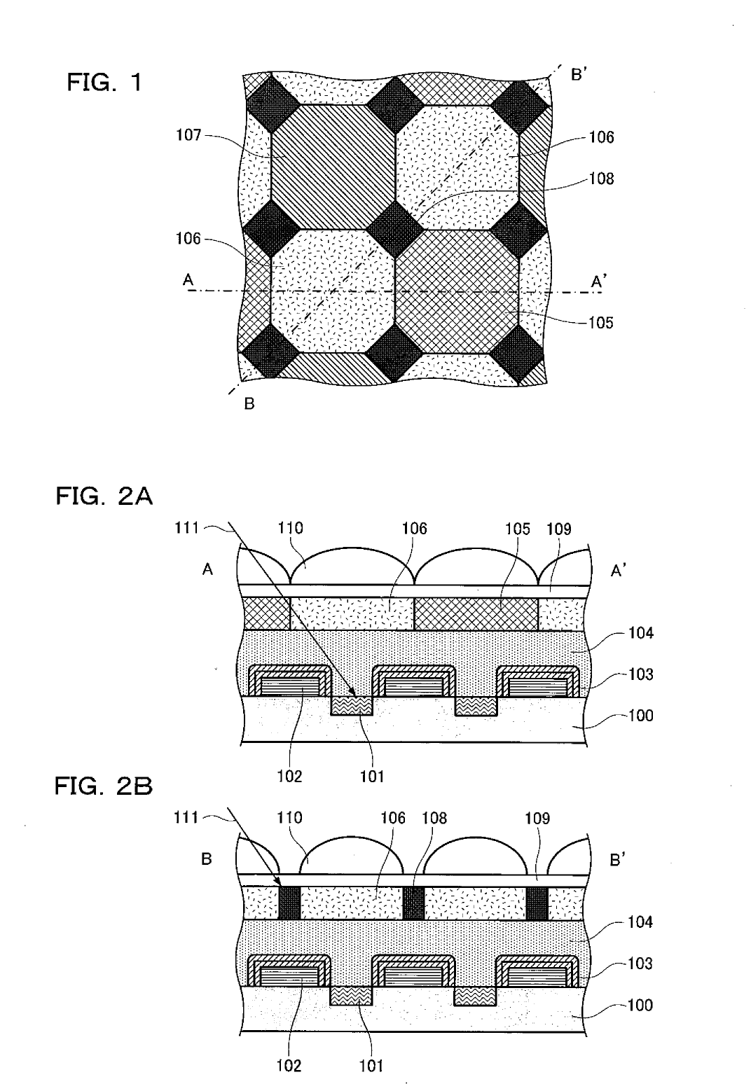

First, referring to FIGS. 1 to 3, the following will schematically describe the configuration of the solid-state image device.

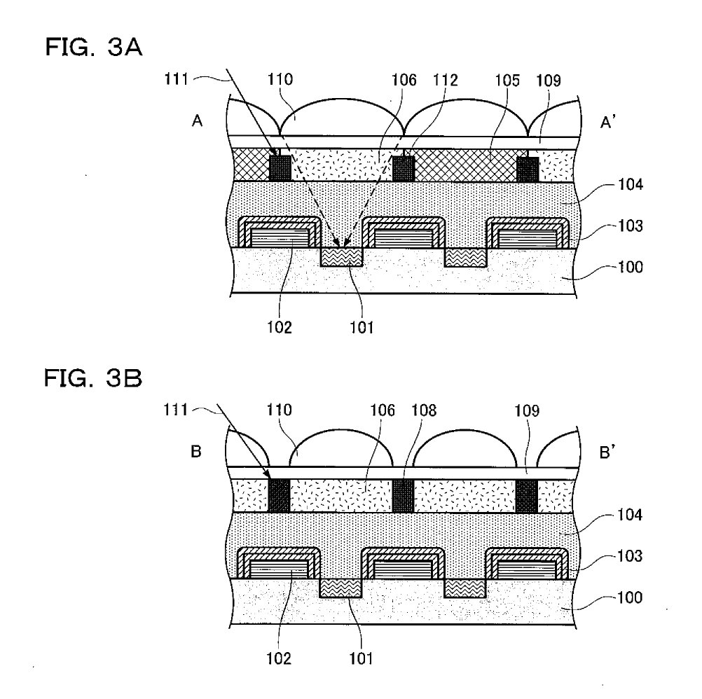

FIG. 1 is a plan view showing the principle part of the configuration of the solid-state image device according to the present invention and also a top view showing the valid pixels of the solid-state image device according to the present invention. FIGS. 2(a) and 2(b) are sectional views showing the configuration of a solid-state image device according to a first embodiment, taken along lines A-A′ and B-B′ of FIG. 1. FIGS. 3(a) and 3(b) are sectional views showing the configuration of a solid-state image device according to a second embodiment, taken along lines A-A′ and B-B′ of FIG. 1. The solid-state image device has a light receiving surface made up of light receiving elements (photodiodes) in a two-dimensional array. FIGS. 2(a) and 2(b) are sectional views showing the two light receiving elements disposed at the center of the light receiving surface. Arrows in FIGS. 2(a) and 2(b) indicate incident light 111 from a light source.

In FIGS. 1 to 3(a) and 3(b), the solid-state image device of the present invention is configured such that a flat transparent film made of a material such as BPSG 104 (boro-phospho-silicate glass) is formed on light receiving portions 101 formed on a silicon semiconductor substrate 100. Stacked on the transparent film are: color filters made of dyes or color resists containing pigments; a transparent film 109 made of a transparent acrylic resin; and microlenses 110. The color filters are made up of Green filters 106 arranged in a checkered pattern, Red filters 107, and Blue filters 105. The Red filters 107 and the Blue filters 105 are formed in alternate lines such that the Red filters 107 and the Blue filters 105 are placed between the Green filters 106 in the alternate lines. In order to reduce color mixture, light shielding films for preventing color mixture, e.g., Black filters 108 in an organic light shielding pattern are placed between the Green filters 106 such that the Black filters 108 are located on the opposite corners of the Green filters 106 arranged in the checkered pattern. Further, on the vertical and horizontal boundaries between adjacent pixels, light shielding films for preventing color mixture, e.g., Black filters 108 are formed that are smaller in thickness than the light shielding films on the opposite corners of the Green filters 106.

The light shielding films for preventing color mixture are disposed between the Green filters 106 such that the light shielding films are located on the opposite corners of the Green filters 106 arranged in the checkered pattern, thereby preventing color mixture caused by the light 111 diagonally incident from an invalid region between the Green filters 106 adjacent to each other in a diagonal direction of the Green filter 106. Since the light shielding films for preventing color mixture are also disposed on the vertical and horizontal boundaries between the adjacent pixels, it is possible to prevent the incident light 111 reflected on the light shielding film formed on a transfer electrode from being incident on the light receiving portion 101 in the vertical and horizontal directions, thereby preventing color mixture from the adjacent pixel.

The following will describe embodiments in accordance with the accompanying drawings.

### First Embodiment

First, referring to FIGS. 1, 2(a) and 2(b), 7(a) to 7(j), and 8(a) to 8(j), a solid-state image device and a method of manufacturing the same will be described below according to a first embodiment.

As shown in FIGS. 1 and 2(a) and 2(b), in the solid-state image device of the present invention, charge transfer electrodes 102 shielded by light shielding films 103 are formed on a silicon semiconductor substrate 100 and light receiving portions 101 are formed between the charge transfer electrodes 102 on the silicon semiconductor substrate 100. On the charge transfer electrodes 102 and the light receiving portions 101, a flat transparent film is formed that is made of a material such as BPSG 104 (boro-phospho-silicate glass). Stacked on the transparent film are: color filters made of dyes or color resists containing pigments; a transparent film 109 made of a transparent acrylic resin; and microlenses 110. In order to reduce color mixture, Black filters 108 in an organic light shielding pattern are disposed as light shielding films for preventing color mixture between Green filters 106 such that the Black filters 108 are located on the opposite corners of the Green filters 106 arranged in a checkered pattern.

In this configuration, a gap between the Green filters 106 in a diagonal direction is rhomboid or substantially rhomboid in top view and a side of the gap is generally about 0.3 μm to 0.6 μm in dimension. The Black filter 108 formed on the gap fills the gap among the Green filter 106, a Red filter 107, and a Blue filter 105 and the Black filter 108 has a thickness of 0.3 μm to 1.5 μm, which ranges from the smallest thickness to the largest thickness of a present color pigment filter. The Black filter 108 filling the gap among these filters should not overlap the Green filter 106, the Red filter 107, or the Blue filter 105. This is because overlapping patterns may cause a height difference resulting in uneven application of filters and flat films in the subsequent process.

As previously mentioned, the Black filters 108 acting as light shielding films for preventing color mixture are disposed between the Green filters 106 such that the Black filters 108 are located on the opposite corners of the Green filters 106 arranged in the checkered pattern. Thus it is possible to prevent color mixture caused by light 111 diagonally incident on the light receiving portion 101 from an invalid region between the Green filters 106 adjacent to each other in a diagonal direction of the Green filter 106, thereby preventing deterioration of image characteristics.

The method of manufacturing the solid-state image device according to the first embodiment includes two methods as will be described below.

### <Method 1 of Manufacturing the Solid-State Image Device>

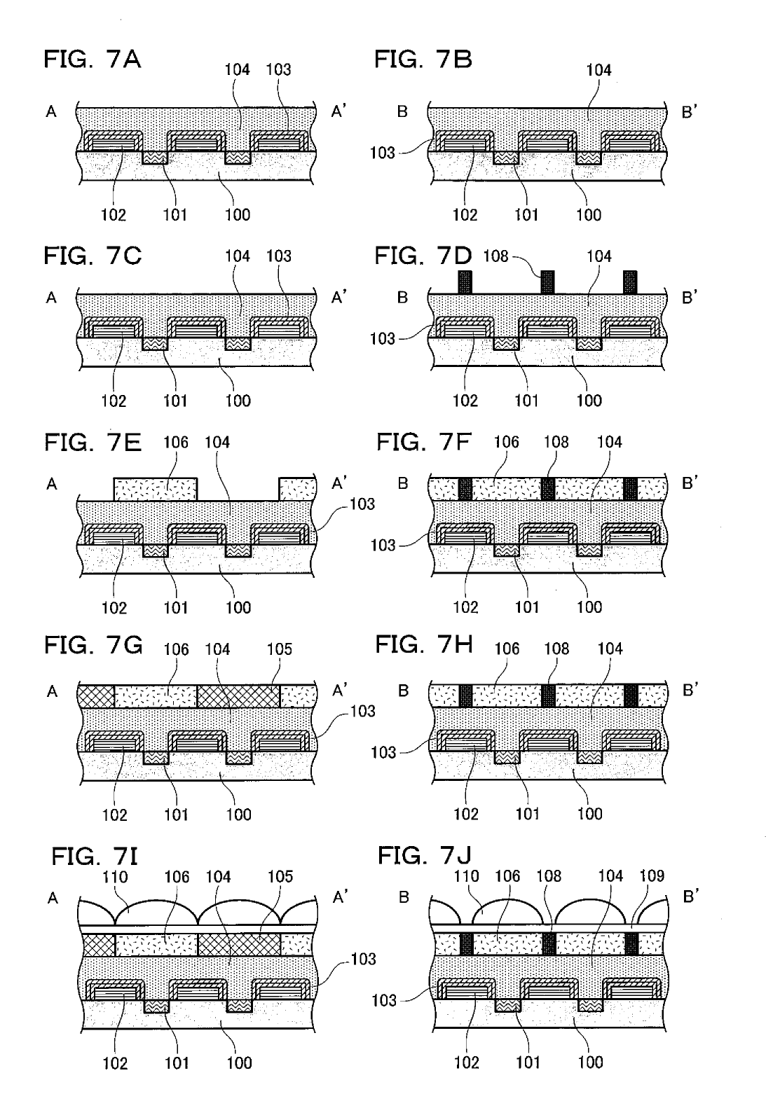

FIGS. 7(a) to 7(j) are process sectional views showing manufacturing process 1 of the solid-state image device according to the first embodiment. FIGS. 7(a), 7(c), 7(e), 7(g), and 7(i) are sectional views taken along line A-A′ of FIG. 1. FIGS. 7(b), 7(d), 7(f), 7(h), and 7(j) are sectional views taken along line B-B′ of FIG. 1.

First, as shown in FIGS. 7(a) and 7(b), the light receiving portions 101, the charge transfer electrodes 102, the light shielding films 103, and the BPSG 104 are formed on the silicon semiconductor substrate 100.

Next, as shown in FIGS. 7(c) and 7(d), the material of the Black filter 108 is applied with a thickness of 0.3 μm to 1.5 μm on the BPSG 104, and is exposed and developed with a photomask so as to leave a pattern on positions corresponding to the gaps between the opposite corners of the Green filters 106, so that the Black filters 108 are patterned.

After that, as shown in FIGS. 7(e) and 7(f), the material of the Green filter 106 is applied with a thickness of 0.3 μm to 1.5 μm, and is exposed and developed with a photomask so as to leave a pattern on the light receiving portions 101 that require the Green filters 106, so that the Green filters 106 are patterned.

Next, as shown in FIGS. 7(g) and 7(h), the materials of the Red filter 107 and the Blue filter 105 are applied with a thickness of 0.3 μm to 1.5 μm and are exposed and developed with a photomask as in the formation of the Green filters 106, so that the Red filters 107 and the Blue filters 105 are formed.

Finally, as shown in FIGS. 7(i) and 7(j), the transparent film 109 under the microlenses is applied with a thickness of 0.1 μm to 1.0 μm and the material of the microlens 110 is applied with a thickness of 0.5 μm to 2.0 μm and is subjected to exposure, development, bleaching, and thermal flow, so that the microlenses 110 are formed.

### <Method 2 of Manufacturing the Solid-State Image Device>

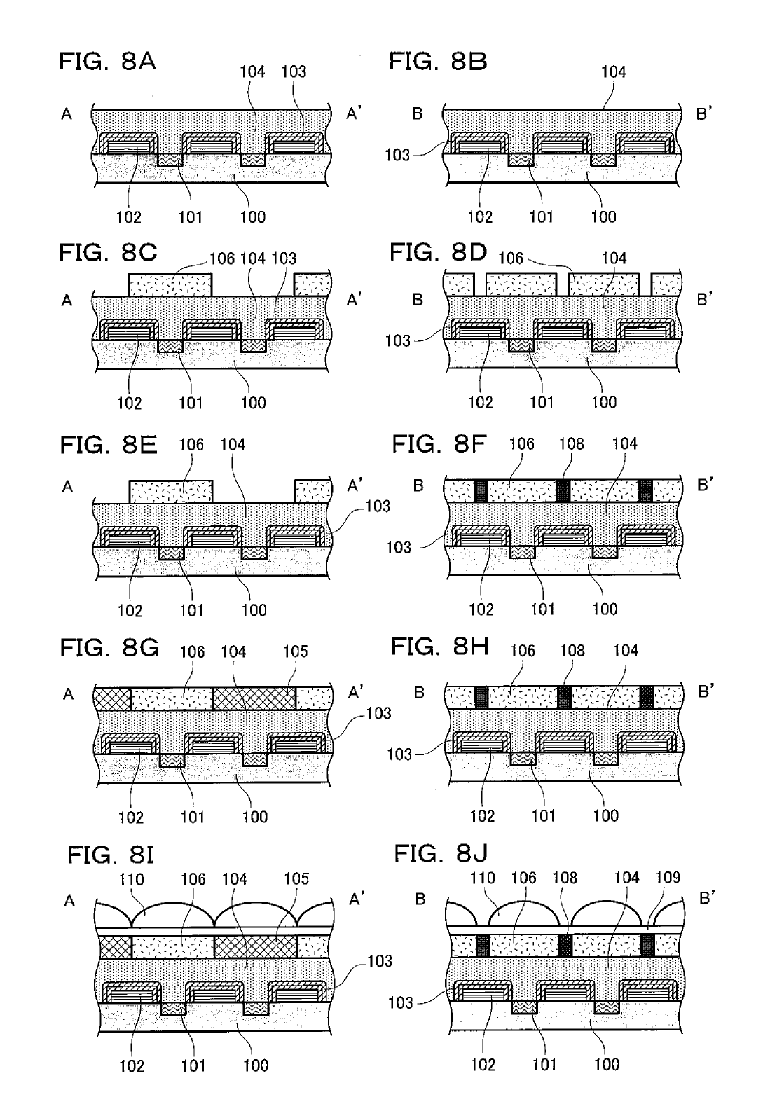

Unlike in method 1 of manufacturing the solid-state image device, the Green filters 106 may be first formed and then the Black filters 108 may be formed on the opposite corners as will be described in manufacturing process 2 of the solid-state image device in FIGS. 8(a) to 8(j).

FIGS. 8(a) to 8(j) are process sectional views showing manufacturing process 2 of the solid-state image device according to the first embodiment. FIGS. 8(a), 8(c), 8(e), 8(g), and 8(i) are sectional views taken along line A-A′ of FIG. 1. FIGS. 8(b), 8(d), 8(f), 8(h), and 8(j) are sectional views taken along line B-B′ of FIG. 1.

First, as shown in FIGS. 8(a) and 8(b), the light receiving portions 101, the charge transfer electrodes 102, the light shielding films 103, and the BPSG 104 are formed on the silicon semiconductor substrate 100.

Next, as shown in FIGS. 8(c) and 8(d), the material of the Green filter 106 is applied with a thickness of 0.3 μm to 1.5 μm on the BPSG 104, and is exposed and developed with a photomask so as to leave a pattern on the light receiving portions 101 that require the Green filters 106, so that the Green filters 106 are patterned. In this case, after the Green filters 106 are formed, the Black filters 108 may be formed before the Red filters 107 and the Blue filters 105, and vice versa.

The present embodiment will describe, as an example, a manufacturing method in which the Black filters 108 are formed after the formation of the Green filters 106.

After the Green filters 106 are formed, as shown in FIGS. 8(e) and 8(f), the material of the Black filter 108 is applied with a thickness of 0.3 μm to 1.5 μm, and is exposed and developed with a photomask so as to leave a pattern on the positions corresponding to the gaps between the opposite corners of the Green filters 106, so that the pattern of the Black filters 108 is formed.

Next, the Red filters 107 and the Blue filters 105 are similarly formed. To be specific, as shown in FIGS. 8(g) and 8(h), the materials of the Red filter 107 and the Blue filter 105 are applied with a thickness of 0.3 μm to 1.5 μm and then are exposed and developed, so that the Red filters 107 and the Blue filters 105 are formed.

Finally, as shown in FIGS. 8(i) and 8(j), the transparent film 109 under the microlenses is applied with a thickness of 0.1 μm to 1.0 μm and the material of the microlens 110 is applied with a thickness of 0.5 μm to 2.0 μm and is subjected to exposure, development, bleaching, and thermal flow, so that the microlenses 110 are formed.

According to these methods, the Black filters 108 acting as light shielding films for preventing color mixture can be disposed between the Green filters 106 such that the Black filters 108 are located on the opposite corners of the Green filters 106 arranged in the checkered pattern. Thus it is possible to prevent color mixture caused by the light 111 diagonally incident on the light receiving portion 101 from the invalid region between the Green filters 106 adjacent to each other in a diagonal direction of the Green filter 106, thereby preventing deterioration of image characteristics.

### Second Embodiment

Referring to FIGS. 1, 3(a) and 3(b), and 9(a) to 9(j), the following will describe a solid-state image device and a method of manufacturing the same according to a second embodiment.

On the vertical and horizontal boundaries among a Red filter 107, a Blue filter 105, and a Green filter 106, incident light 111 from an adjacent pixel may be reflected on a light shielding film 103 and sensitivity may decline. In order to address this problem in the solid-state image device of the second embodiment, Black filters 112 are formed on the vertical and horizontal boundaries between adjacent pixels in the respective color filters as shown in FIGS. 3(a) and 3(b), unlike in the solid-state image device of the first embodiment. The Black filters 112 are smaller in thickness than Black filters 108 disposed on the opposite corners of the Green filters 106. The Black filters 112 formed on the vertical and horizontal boundaries are 0.2 μm to 0.6 μm in dimension in plan view and are 0.3 μm to 1.3 μm in thickness.

In the vertical and horizontal directions, the light 111 having been condensed through microlenses 110 and incident near the boundaries may be reflected on the Black filters 112 for shielding light without being incident on light receiving portions 101, resulting in a decline in sensitivity. For this reason, the Black filters 112 have to be smaller in thickness than the Black filters 108 disposed on the opposite corners of the Green filters 106. Thus the Black filters 108 on the opposite corners are 0.3 μm to 1.5 μm in thickness, whereas the Black filters 112 arranged in the vertical and horizontal directions are 0.3 μm to 1.3 μm in thickness.

As previously mentioned, the Black filters 108 acting as light shielding films for preventing color mixture are disposed between the Green filters 106 such that the Black filters 108 are located on the opposite corners of the Green filters 106 arranged in a checkered pattern, and the Black filters 112 shorter than the Black filters 108 are provided on the boundaries between the filters and the pixels adjacent to the filters in the vertical and horizontal directions of the respective color pixels. Thus it is possible to prevent color mixture occurring when the light 111 is diagonally incident on the light receiving portion 101 from an invalid region between the Green filters 106 adjacent to each other in a diagonal direction of the Green filter 106, and it is possible to prevent color mixture occurring when the incident light 111 is reflected on the light shielding film 103 and is incident on the light receiving portion 101 from the pixels adjacent in the vertical and horizontal directions of the respective color pixels, thereby preventing deterioration of image characteristics.

The following will describe the method of manufacturing the solid-state image device according to the second embodiment.

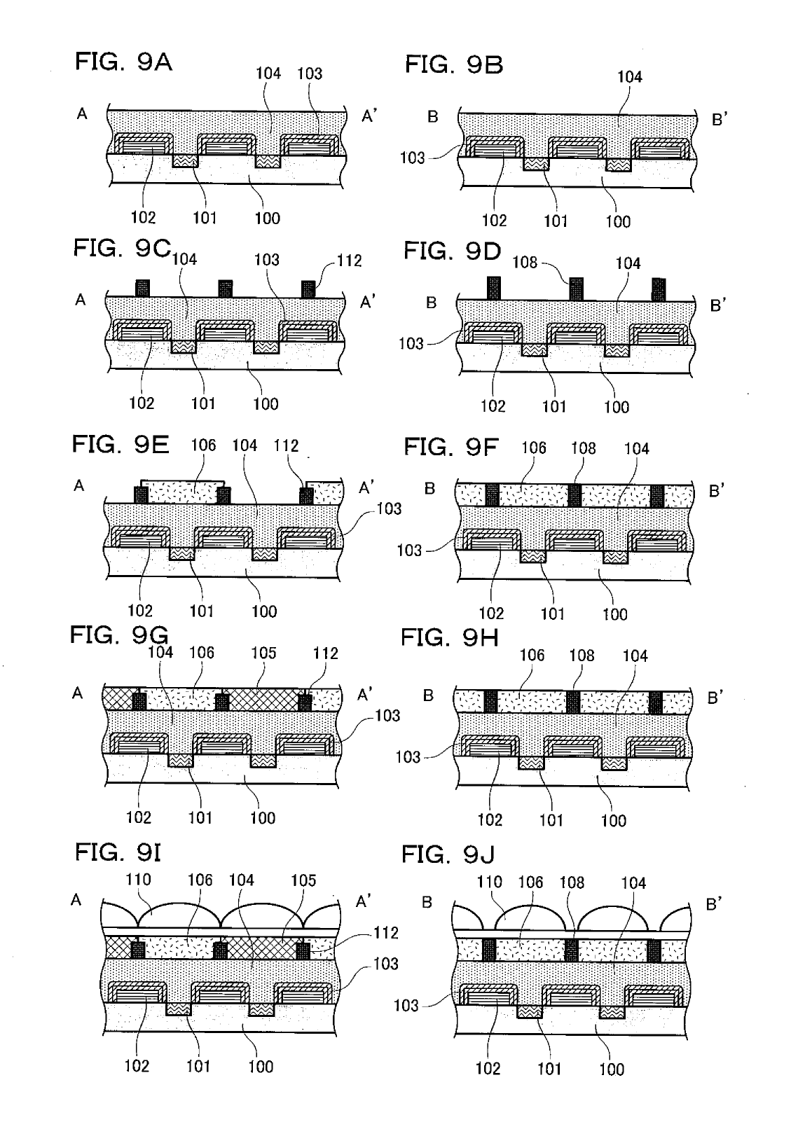

FIGS. 9(a) to 9(j) are process sectional views showing the manufacturing process of the solid-state image device according to the second embodiment. FIGS. 9(a), 9(c), 9(e), 9(g), and 9(i) are sectional views taken along line A-A′ of FIG. 1. FIGS. 9(b), 9(d), 9(f), 9(h), and 9(j) are sectional views taken along line B-B′ of FIG. 1.

The steps are basically similar to those of FIGS. 7(a) to 7(j). The Black filters 108 for the light shielding films formed on the opposite corners of the Green filters 106 are different in thickness from the Black filters 112 for the light shielding films formed between the filters adjacent to each other in the vertical and horizontal directions. Thus the Black filters are simultaneously formed with a gray scale mask (halftone mask).

First, as shown in FIGS. 9(a) and 9(b), the light receiving portions 101, charge transfer electrodes 102, the light shielding films 103, and BPSG 104 are formed on a silicon semiconductor substrate 100.

Next, as shown in FIGS. 9(c) and 9(d), the materials of the Black filter 108 and the Black filter 112 for shielding light are applied with a thickness of 0.3 μm to 1.5 μm on the BPSG 104, the mask of the pixel boundaries in the vertical and horizontal directions has a different gray scale from the mask of the opposite corners of the Green filters, the materials are exposed and developed with a gray scale mask to adjust an amount of irradiation during the exposure, and patterning is performed at positions corresponding to the opposite corners of the Green filters 106 and the pixel boundaries in the vertical and horizontal directions, so that the Black filters 108 and the Black filters 112 shorter than the Black filters 108 are formed.

After that, as shown in FIGS. 9(e) and 9(f), the material of the Green filter 106 is applied with a thickness of 0.3 μm to 1.5 μm, and is exposed and developed with a photomask so as to leave a pattern on the light receiving portions 101 that require the Green filters 106, so that the Green filters 106 are patterned.

Next, as shown in FIGS. 9(g) and 9(h), the Red filters 107 and Blue filters 105 are formed like the Green filters 106.

Finally, as shown in FIGS. 9(i) and 9(j), a transparent film 109 under microlenses is applied with a thickness of 0.1 μm to 1.0 μm and the material of the microlens 110 is applied with a thickness of 0.5 μm to 2.0 μm and is subjected to exposure, development, bleaching, and thermal flow, so that the microlenses 110 are formed.

According to this method, the Black filters 108 acting as light shielding films for preventing color mixture can be disposed between the Green filters 106 such that the Black filters 108 are located on the opposite corners of the Green filters 106 arranged in a checkered pattern, and the Black filters 112 shorter than the Black filters 108 can be provided on the boundaries between the filters and the pixels adjacent to the filters in the vertical and horizontal directions of the respective color pixels. Thus it is possible to prevent color mixture occurring when the light 111 is diagonally incident on the light receiving portion 101 from an invalid region between the Green filters 106 adjacent to each other in a diagonal direction of the Green filter 106, and it is possible to prevent color mixture occurring when the incident light 111 is reflected on the light shielding film 103 and is incident on the light receiving portion 101 from the pixels adjacent in the vertical and horizontal directions of the respective color pixels, thereby preventing deterioration of image characteristics.

### Third Embodiment

Referring to FIGS. 1, 4(a) and 4(b), 5(a) and 5(b), 10(a) to 10(f), and 11(a) to 11(f), the following will describe a solid-state image device and a method of manufacturing the same according to a third embodiment.

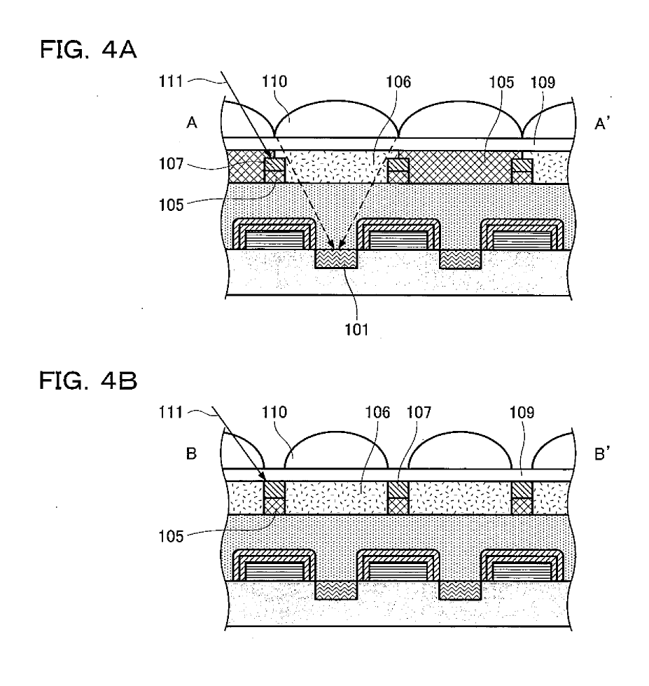

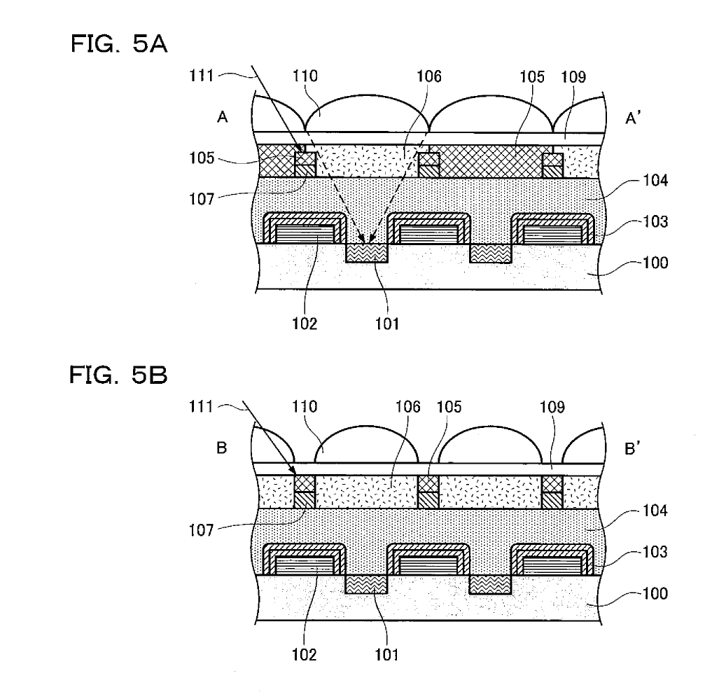

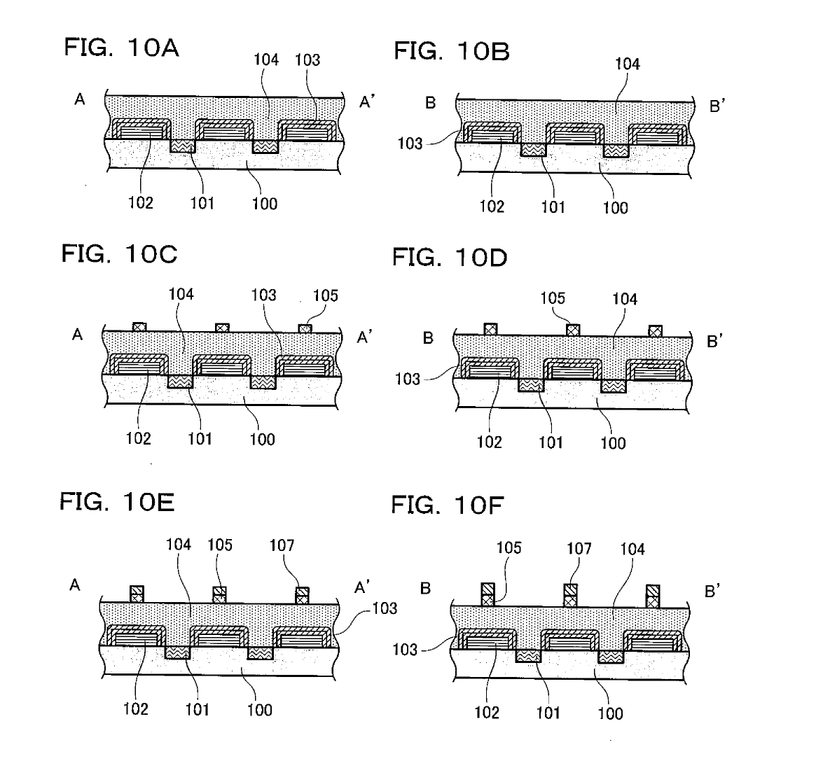

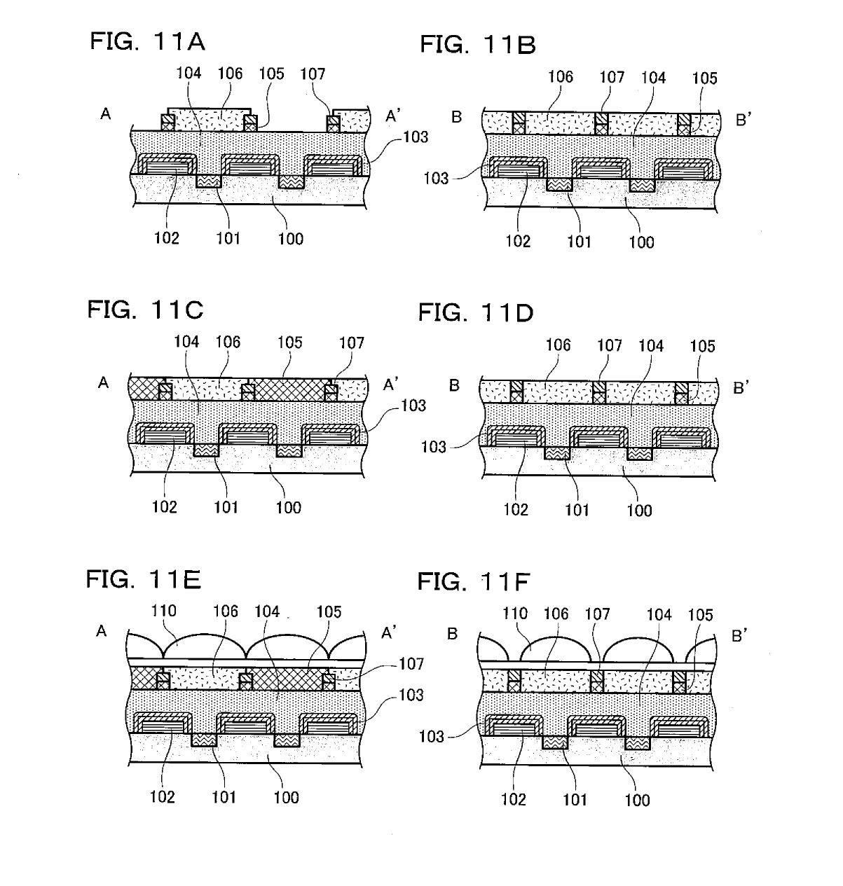

FIGS. 4(a) and 4(b) are sectional views showing the configuration of the solid-state image device in which light shielding films are formed by stacking Red filters on Blue filters according to the third embodiment. FIGS. 5(a) and 5(b) are sectional views showing the configuration of the solid-state image device in which the light shielding films are formed by stacking the Blue filters on the Red filters according to the third embodiment. FIGS. 10(a) to 10(f) and 11(a) to 11(f) are process sectional views showing the manufacturing process of the solid-state image device according to the third embodiment. FIGS. 10(a), 10(c), 10(e), 11(a), 11(c), and 11(e) are sectional views taken along line A-A′ of FIG. 1. FIGS. 10(b), 10(d), 10(f), 11(b), 11(d), and 11(f) are sectional views taken along line B-B′ of FIG. 1.

In the third embodiment, instead of the Black filter 108 and the Black filter 112 of the first or second embodiment, a laminate of a Blue filter 105 and a Red filter 107 is used as a light shielding film for preventing color mixture. The stacked Blue filter and Red filter can cut off light at a wavelength of about 400 nm to 500 nm and light at a wavelength of about 600 nm to 700 nm, respectively. Thus it is possible to achieve substantially the same effect as the Black filter. In this case, laminates formed on the opposite corners of Green filters have dimensions of about 0.3 μm to 0.6 μm in plan view and the laminate of the Blue filter 105 and the Red filter 107 is 0.3 μm to 1.5 μm in thickness. Moreover, laminates formed on the vertical and horizontal boundaries have dimensions of 0.3 μm to 0.6 μm in plan view and are 0.3 μm to 1.3 μm in thickness. The Blue filter 105 and the Red filter 107 may be formed in any order.

For example, as shown in FIGS. 4(a) and 4(b) and 5(a) and 5(b), the laminate of the Blue filter 105 and the Red filter 107 is formed instead of the light shielding films, which are formed by the Black filter 108 and the Black filter 112, for preventing color mixture in FIGS. 2(a) and 2(b) and 3(a) and 3(b). In FIGS. 4(a) and 4(b) and 5(a) and 5(b), the constituent elements illustrated in FIGS. 2(a) and 2(b) and 3(a) and 3(b) are indicated by the same reference numerals and the explanation thereof is omitted. In the laminate of FIGS. 4(a) and 4(b), the Red filter 107 is stacked on the Blue filter 105. In the laminate of FIGS. 5(a) and 5(b), the Blue filter 105 is stacked on the Red filter 107.

Regarding the method of manufacturing the solid-state image device according to the third embodiment, a method of manufacturing the solid-state image device in FIGS. 4(a) and 4(b) will be described as an example.

First, as shown in FIGS. 10(a) and 10(b), light receiving portions 101, charge transfer electrodes 102, light shielding films 103, and BPSG 104 are formed on a silicon semiconductor substrate 100.

Next, as shown in FIGS. 10(c) and 10(d), the material of the Blue filter 105 is applied with a thickness of 0.3 μm to 1.5 μm on the BPSG 104, is exposed and developed with a gray scale mask, and is patterned at positions corresponding to the opposite corners of Green filters 106. At this point, the mask of pixel boundaries in the vertical and horizontal directions has a different gray scale from the mask of the opposite corners, an amount of irradiation during the exposure is adjusted, and a filter thickness is reduced between pixels adjacent to each other in the vertical and horizontal directions.

After that, as shown in FIGS. 10(e) and 10(f), the material of the Red filter 107 is applied with a thickness of 0.3 μm to 1.5 μm, the mask of the pixel boundaries in the vertical and horizontal directions has a different gray scale from the mask of the opposite corners, and the material is exposed and developed using a gray scale mask with an adjusted amount of irradiation during the exposure, so that the light shielding films for preventing color mixture are patterned. In the light shielding film, the Red filter 107 is stacked on the Blue filter 105.

Next, as shown in FIGS. 11(a) and 11(b), the material of the Green filter 106 is applied with a thickness of 0.3 μm to 1.5 μm, and is exposed and developed with a photomask so as to leave a pattern on the light receiving portions 101 that require the Green filters 106, so that the Green filters 106 are patterned.

After that, as shown in FIGS. 11(c) and 11(d), the Red filters 107 and the Blue filters 105 are formed like the Green filters 106.

Finally, as shown in FIGS. 11(e) and 11(f), a transparent film 109 under microlenses is applied with a thickness of 0.1 μm to 1.0 μm and the material of a microlens 110 is applied with a thickness of 0.5 μm to 2.0 μm and is subjected to exposure, development, bleaching, and thermal flow, so that the microlenses 110 are formed.

In the manufacturing of the solid-state image device shown in FIGS. 5(a) and 5(b), the Blue filter 105 and the Red filter 107 are exchanged with each other in the steps of FIGS. 10(c) to 10(f).

In this way, the light shielding films, in which the Red filters 107 are stacked on the Blue filters 105, for preventing color mixture are disposed between the Green filters 106 such that the light shielding films are located on the opposite corners of the Green filters 106 arranged in a checkered pattern, or the light shielding films, in which the Red filters 107 are stacked on the Blue filters 105, for preventing color mixture are further provided on the boundaries between the filters and the pixels adjacent to the filters in the vertical and horizontal directions of the respective color pixels, the light shielding films being shorter than the light shielding films for preventing color mixture on the opposite corners of the Green filters 106. Thus it is possible to prevent color mixture occurring when light 111 is diagonally incident on the light receiving portion 101 from an invalid region between the Green filters 106 adjacent to each other in a diagonal direction of the Green filter 106, and it is possible to prevent color mixture occurring when the incident light 111 is reflected on the light shielding film 103 and is incident on the light receiving portion 101 from the pixels adjacent in the vertical and horizontal directions of the respective color pixels, thereby preventing deterioration of image characteristics.

### Fourth Embodiment

Referring to FIGS. 1, 6(a) and 6(b), and 12(a) to 12(j), the following will describe a solid-state image device and a method of manufacturing the same according to a fourth embodiment.

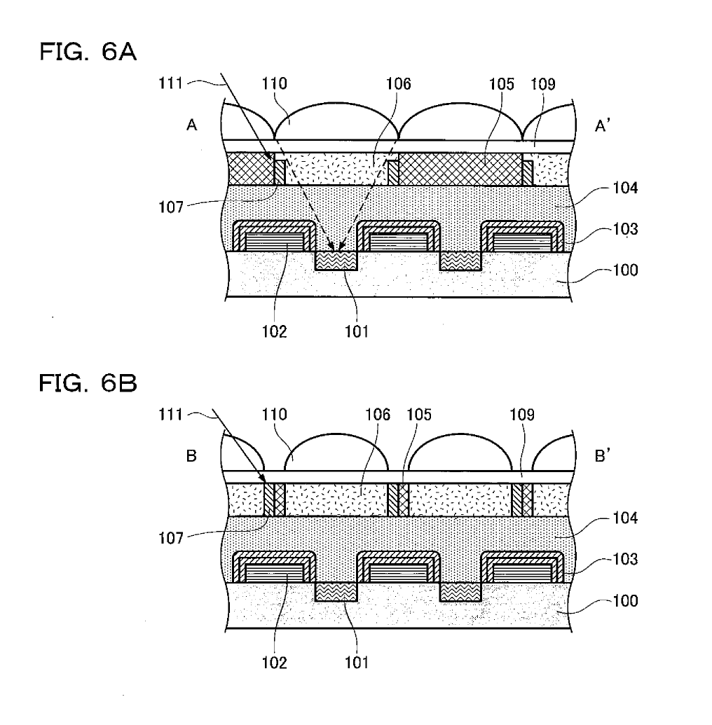

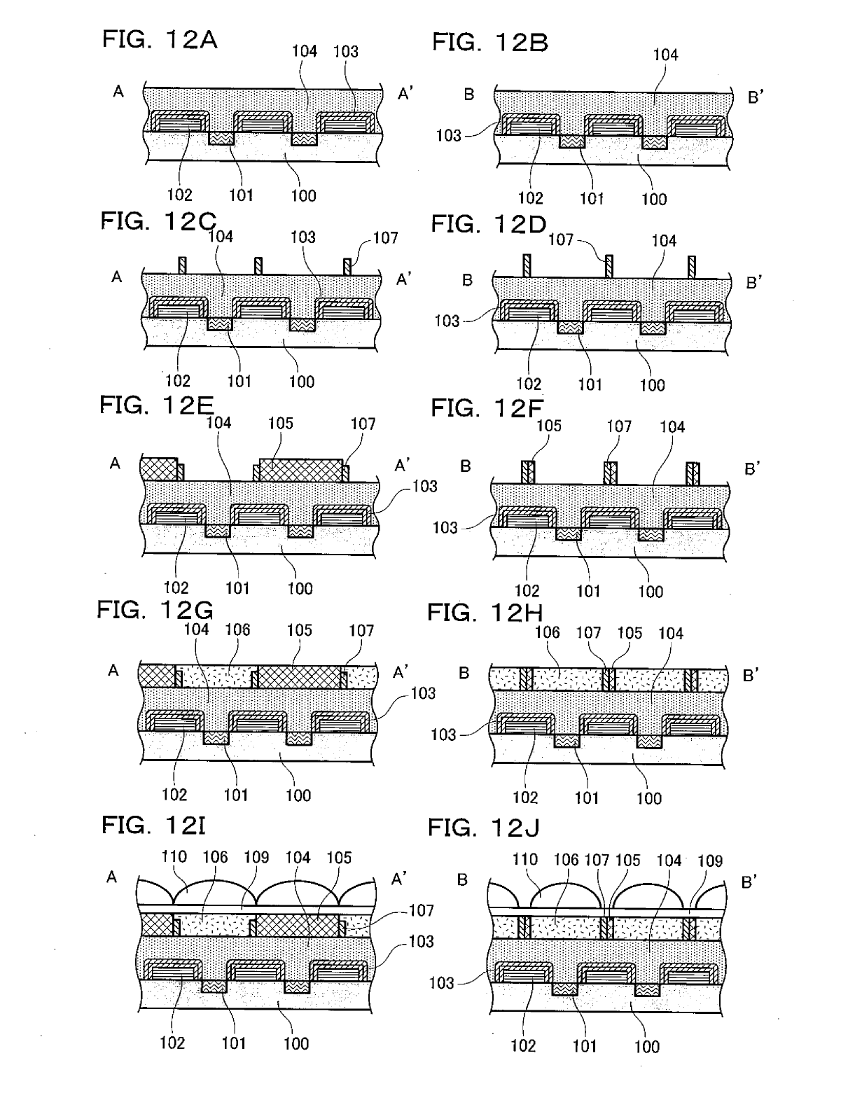

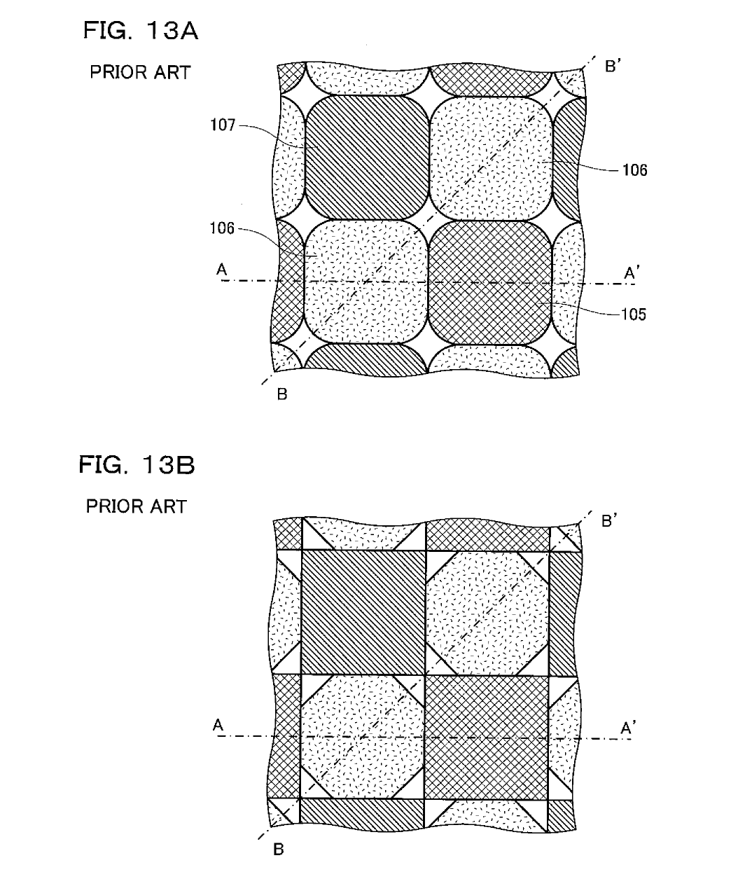

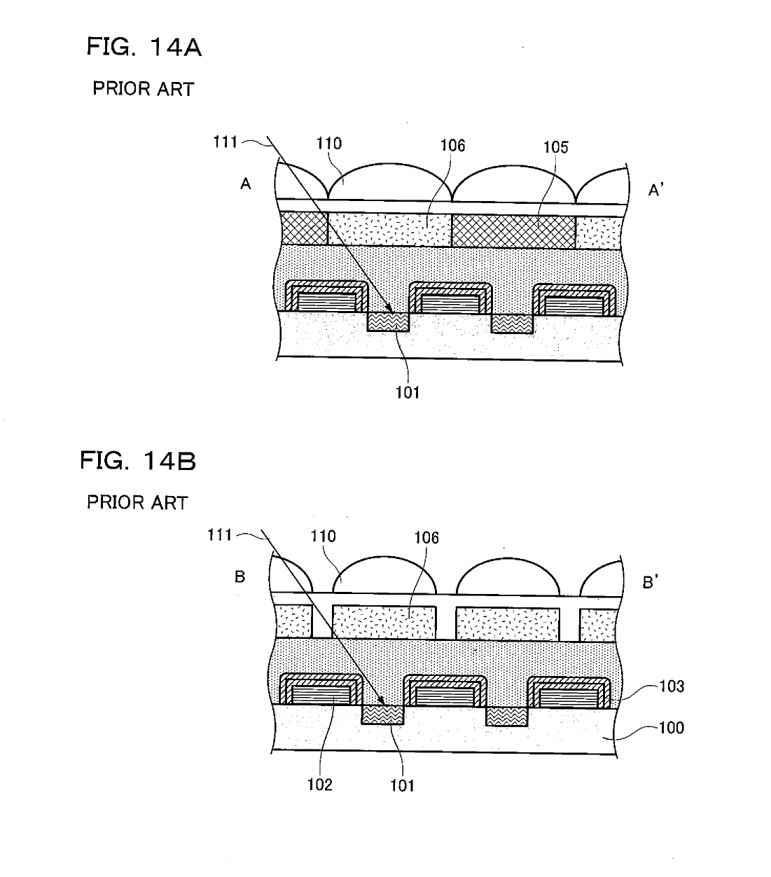

FIGS. 6(a) and 6(b) are sectional views showing the configuration of the solid-state image device according to the fourth embodiment. FIGS. 12(a) to 12(j) are process, sectional views showing the manufacturing process of the solid-state image device according to the fourth embodiment. FIGS. 12(a), 12(c), 12(e), 12(g), and 12(i) are sectional views taken along line A-A′ of FIG. 1. FIGS. 12(b), 12(d), 12(f), 12(h), and 12(j) are sectional views taken along line B-B′ of FIG. 1.

The solid-state image device of the third embodiment is formed by stacking the Red filters 107 and Blue filters 105 for shielding light, whereas in the solid-state image device of the fourth embodiment, Red filters 107 and Blue filters 105 are arranged in parallel as shown in FIGS. 6(a) and 6(b) and the same effect is obtained as Black filters 108 and Black filters 112. In this configuration, on the vertical and horizontal boundaries of the Blue filters 105 and the Red filters 107 with Green filters 106, only the Red filters 107 are formed on the boundaries between the Blue filters 105 and the Green filters 106 and only the Blue filters 105 are formed on the boundaries between the Red filters 107 and the Green filters 106.

The following will describe the method of manufacturing the solid-state image device according to the fourth embodiment.

First, as shown in FIGS. 12(a) and 12(b), light receiving portions 101, charge transfer electrodes 102, light shielding films 103, and BPSG 104 are formed on a silicon semiconductor substrate 100.

Next, as shown in FIGS. 12(c) and 12(d), the material of the Blue filter 105 or the Red filter 107 is applied with a thickness of 0.3 μm to 1.5 μm on the BPSG 104, a mask has a different gray scale in the vertical and horizontal directions from a mask on the opposite corners of the Green filters, and the material is exposed and developed using a gray scale mask with an adjusted amount of irradiation during the exposure, so that the Blue filters 105 or the Red filters 107 are patterned.

After that, as shown in FIGS. 12(e) and 12(f), the material of the Red filter 107 (Blue filter 105) is applied with a thickness of 0.3 μm to 1.5 μm, and is exposed and developed using a gray scale mask, so that the Red filters 107 (Blue filters 105) are patterned. Consequently, light shielding films are formed on the light receiving portions 101, the opposite corners of the Green filters 106, and pixel boundaries in the vertical and horizontal directions. At this point, the mask of the pixel boundaries in the vertical and horizontal directions has a different gray scale from the mask of the opposite corners, and an amount of irradiation during the exposure is adjusted.

After the Red filters 107 (Blue filters 105) are formed, the Blue filters 105 (Red filters 107) are similarly formed.

In this configuration, the Red filters 107 may be simultaneously formed on the light receiving portions 101, the opposite corners of the Green filters 106, and the pixel boundaries in the vertical and horizontal directions by adjusting the thickness with the adjusted amount of irradiation during the exposure. Similarly, the Blue filters 105 may be simultaneously formed on the light receiving portions 101, the opposite corners of the Green filters 106, and the pixel boundaries in the vertical and horizontal directions by adjusting the thickness with the adjusted amount of irradiation during the exposure.

Next, as shown in FIGS. 12(g) and 12(h), the material of the Green filter 106 is applied with a thickness of 0.3 μm to 1.5 μm, and is exposed and developed with a photomask so as to leave a pattern on the light receiving portions 101 that require the Green filters 106, so that the Green filters 106 are patterned.

Finally, as shown in FIGS. 12(i) and 12(j), a transparent film 109 under microlenses is applied with a thickness of 0.1 μm to 1.0 μm and the material of a microlens 110 is applied with a thickness of 0.5 μm to 2.0 μm and is subjected to exposure, development, bleaching, and thermal flow, so that the microlenses 110 are formed.

As previously mentioned, the light shielding films, each of which is made up of the Blue filter 105 and the Red filter 107, for preventing color mixture are disposed between the Green filters 106 such that the light shielding films are located on the opposite corners of the Green filters 106 arranged in a checkered pattern, or the light shielding films, each of which is made up of the Blue filter 105 or the Red filter 107, for preventing color mixture are further provided on the boundaries between the filters and pixels adjacent to the filters in the vertical and horizontal directions of the respective color pixels, the light shielding films being shorter than the light shielding films for preventing color mixture on the opposite corners of the Green filters 106. Thus it is possible to prevent color mixture occurring when light 111 is diagonally incident on the light receiving portion 101 from an invalid region between the Green filters 106 adjacent to each other in a diagonal direction of the Green filter 106, and it is possible to prevent color mixture occurring when the incident light 111 is reflected on the light shielding film 103 and is incident on the light receiving portion 101 from the pixels adjacent in the vertical and horizontal directions of the respective color pixels, thereby preventing deterioration of image characteristics.

### INDUSTRIAL APPLICABILITY

The present invention is useful for a solid-state image device in which a plurality of light receiving elements formed on a semiconductor substrate each have a color filter and a microlens, and a method of manufacturing the same. The present invention can prevent deterioration of image characteristics by suppressing color mixture while keeping sensitivity characteristics.

What is claimed is:

1. A solid-state image device, comprising:
a plurality of light receiving portions formed on a substrate;
Green filters formed in a checkered pattern on the light receiving portions;
Blue filters and Red filters formed in alternate lines such that the Blue filters and the Red filters are placed between the Green filters in the alternate lines;
a microlens formed on each of the Green filters, the Blue filters, and the Red filters; and
first light shielding films for preventing color mixture, the first light shielding film being formed in a gap between the Green filters adjacent to each other in a diagonal direction.

2. The solid-state image device according to claim 1, further comprising second light shielding films for preventing color mixture, wherein the second light shielding films are formed on boundaries between the Blue filters and the Green filters and boundaries between the Red filters and the Green filters, and the second light shielding film is smaller in thickness than the first light shielding film for preventing color mixture.

3. The solid-state image device according to claim 1, wherein the first light shielding film for preventing color mixture is a Black filter.

4. The solid-state image device according to claim 2, wherein the first light shielding film for preventing color mixture and the second light shielding film for preventing color mixture are Black filters.

5. The solid-state image device according to claim 1, wherein the first light shielding film for preventing color mixture is a film made up of the Blue filter and the Red filter.

6. The solid-state image device according to claim 2, wherein the first light shielding film for preventing color mixture and the second light shielding film for preventing color mixture are films each of which is made up of the Blue filter and the Red filter.

7. The solid-state image device according to claim 5, wherein the Blue filter and the Red filter are stacked.

8. The solid-state image device according to claim 6, wherein the Blue filter and the Red filter are stacked.

9. A method of manufacturing a solid-state image device, the solid-state image device comprising:
a plurality of light receiving portions constituting a light receiving surface;
color filters; and
microlenses,
the color filters and microlenses corresponding to the respective light receiving portions,
when the color filters are formed, the method comprising the steps of:
forming Green filters in a checkered pattern;
forming first Black filters in gaps between the Green filters adjacent to each other in a diagonal direction; and
forming Blue filters and Red filters.

10. The method of manufacturing a solid-state image device according to claim 9, further comprising the step of forming second Black filters on boundaries between the Blue filters and the Green filters and boundaries between the Red filters and the Green filters, concurrently with the step of forming the first Black filters, the second Black filter being smaller in thickness than the first Black filter.

11. The method of manufacturing a solid-state image device according to claim 9, wherein the first Black filter is replaced with a laminate of the Blue filter and the Red filter.

12. The method of manufacturing a solid-state image device according to claim 10, wherein the first Black filter and the second Black filter are each replaced with a laminate of the Blue filter and the Red filter.

13. A method of manufacturing a solid-state image device, the solid-state image device comprising:
a plurality of light receiving portions constituting a light receiving surface;
color filters; and
microlenses,
the color filters and microlenses corresponding to the respective light receiving portions,
when the color filters are formed, the method comprising the steps of:
forming second Red filters acting as first light shielding films for preventing color mixture such that the second Red filters are formed in gaps between Green filters adjacent to each other in a diagonal direction, concurrently with first Red filters acting as the color filters;
forming second Blue filters acting as the first light shielding films for preventing color mixture such that the second Blue filters are formed in the gaps between the Green filters adjacent to each other in the diagonal direction, concurrently with first Blue filters acting as the color filters; and
forming the Green filters in a checkered pattern such that the first light shielding films for preventing color mixture are disposed in the gaps between the Green filters adjacent to each other in the diagonal direction,
wherein the first light shielding film for preventing color mixture is configured such that the second Blue filter and the second Red filter are arranged in parallel.

14. The method of manufacturing a solid-state image device according to claim 13, further comprising the steps of:
forming third Red filters on boundaries between the first Blue filters and the Green filters in the step of forming the first and second Red filters, the third Red filter acting as a second light shielding film for preventing color mixture; and
forming third Blue filters on boundaries between the first Red filters and the Green filters in the step of forming the first and second Blue filters, the third Blue filter acting as the second light shielding film for preventing color mixture,
wherein the second light shielding film for preventing color mixture is smaller in thickness than the first light shielding film for preventing color mixture.
